(19) United States
(12) Patent Application Publication
(10) Pub. No.: US 2009/0085598 A1
(43) Pub. Date: Apr. 2, 2009

(54) INTEGRATED CIRCUIT TEST SYSTEM AND METHOD WITH TEST DRIVER SHARING

(75) Inventors: Markus Kollwitz, Neubiberg (DE); Rahul Mukerjee, Unterhaching (DE); Jimenez Olivares, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/863,920

(22) Filed: Sep. 28, 2007

(51) Int. Cl. G01R 31/26

(52) U.S. Cl. 324/765

(57) ABSTRACT

An integrated circuit test system and method for testing integrated circuits or chips is disclosed. One embodiment provides a test signal from a test driver via a primary test channel and distributed via parallel wiring paths to a plurality of contact pads of one or more integrated circuits or chips under test. At least one operational amplifier is arranged in the wiring path connected to the contact pads of the integrated circuits or chips.

### BACKGROUND

The present invention relates to a system and a method with test driver sharing for testing a plurality of integrated circuits on a wafer, devices or chips. In one embodiment, the system includes an interface or a probe card with active components for connecting a testing system to a plurality of integrated circuits on a wafer, devices or chips using test driver sharing.

In conventional semiconductor manufacturing, a plurality of integrated circuits or devices are formed on a semiconductor substrate or wafer, and after completing the fabrication processes, the devices formed on the wafer may be cut from the wafer and packaged into individual chips, which are then tested individually to ensure that each chip performs according to the required specifications. To reduce costs associated with testing chips individually, the devices formed on the wafer may be tested prior to being separated into individual chips. Conducting tests on integrated circuits or devices formed on a wafer generally improves cost efficiencies and also facilitates sales of devices on a wafer level (i.e., sales of device wafers or IC wafers).

Probe cards are used to test the performance, internal connections or characteristics of IC wafers with a plurality of integrated circuits formed thereon. A typical probe card is provided with a probe corresponding to an electrode pad formed on each integrated circuit on an IC wafer. Thereby, the probe card serves as an interface for connecting a testing system to a plurality of integrated circuits on the IC wafer.

Currently, to test a wafer having a plurality of devices formed thereon, a probe card having a plurality of probes is utilized to provide physical contact with a plurality of contact pads of the devices formed on the device wafer. Such contact pads are electrically conductive pads which are connected to the leads (e.g., input, output, reference voltage, ground, etc.) of the devices. By pressing the probe of the probe card onto the electrode pad of an integrated circuit, tests of electric connection of the pad, such as an open test and a short test, or test of the functionality of the integrated circuit can be performed.

In conventional testing systems, a probe card cannot test all integrated circuits or devices on a wafer at once and requires sequential testing of groups of devices, resulting in prolonged testing time and reducing throughput. Because a probe card provides a limited number of probes corresponding to the number of available test channels on the tester or testing equipment, the integrated circuits or devices formed on the wafer are divided into a plurality of groups for testing purposes. Each group of devices may be tested utilizing one probe card, and the testing processes are repeated for each group of devices.

Since the integrated circuits, devices or chips on the wafer cannot be tested at the same time (e.g., cannot be tested with the same touchdown of the probe card), some tests may require excessively long time periods to be completed, particularly with tests such as burn-in tests which may require days to be completed for all devices, integrated circuits on a wafer or chips. Such excessive time requirements for performing device testing substantially reduces production efficiencies and throughput. Furthermore, a probe card may require an excessive number of touchdowns on the contact pads on the wafer, which is time consuming and may result in damages to the integrated circuits or devices formed thereon.

In the effort to defeat the backlashes, it is known to use a shared driver channel which is connected to the same type of input pad for several chips or integrated circuits on a wafer. For this sake, known test systems are equipped with a certain number of output channels that enable a certain number of integrated circuits or chips to be tested in parallel. In order to save costs, it is desirable to increase parallelism, to which end one test driver DRV is no longer connected to one pin of a chip but is connected in parallel to functionally identical pins of a plurality of chips, which is known as the shared driver concept. For example, as illustrated in the enclosed FIG. 1, a test signal from a transmit or tester driver DRV is distributed in parallel to four functionally identical pads X of four integrated circuits on a wafer or chips under test via a primary test channel PTC having a line impedance of 50 Ohms.

In a conventional test system as illustrated in FIG. 1, based on the shared driver concept, the inputs of the chips under test do not draw more current in total than the tester driver DRV can supply. If a failure in the integrated circuit or chip causes a short-circuit in one of the pads X of the integrated circuit or chip, an input impedance of about 0 Ohms occurs on the respective pads X. Thus, the test signal on the related primary test channel PTC becomes zero (0 V) and is therefore no longer available for the other integrated circuits or chips connected to the primary test channel PTC either. This means that the one faulty integrated circuit or chip turns the other potentially good integrated circuits or chips into failed devices during testing, thereby reducing the yield. In conclusion, the known technology of a shared driver channel is connected with yield loss due to negative interaction by shared faulty integrated circuits or chips, e.g., integrated circuits or chips having a short-circuit, causing an input impedance of about 0 Ohms occurs on the involved pads of the faulty integrated circuits or chips.

Furthermore, known shared driver technologies suffer from parallelism limitations, i.e. non gated internal test voltages are currently not shared, since the yield loss would be too high. The parallelism limitations also occur, if the number of shared contact pads is limited by the signal quality requirements. Parallelism limitations may be further caused by the requirement to provide several voltages with separate channels. Another problem of known technologies resides in voltage drop, when the integrated circuit or chip is consuming current on a certain contact pad, the voltage level is dropping due to the internal 50 Ohm resistance of a standard tester driver of a conventional test system.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates schematically a prior known test system.

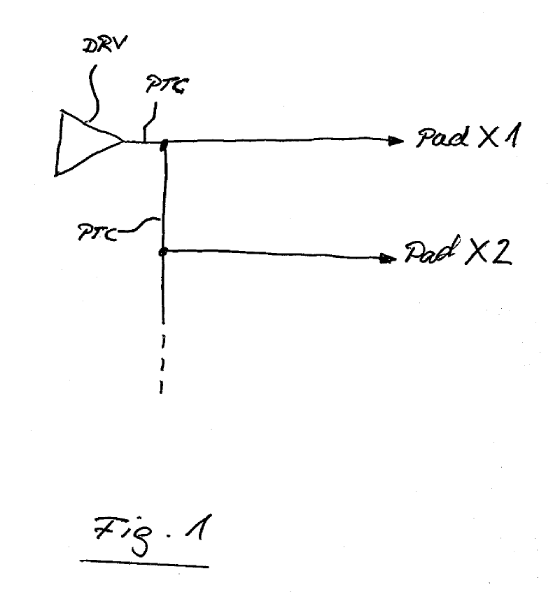

FIG. 2 illustrates an embodiment of a test system according to the present invention;

FIG. 3 illustrates another embodiment of a test system according to the present invention;

FIG. 4 illustrates another embodiment of a test system according to the present invention; and

FIG. 5 illustrates another embodiment of a test system according to the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

The present invention aims to reduce or overcome the above mentioned problems of known technologies. More particular, the present invention aims to further develop the shared driver concept with a generic test system reducing the loss of yield from potentially faulty or short-circuited chips.

According to one embodiment, a system is made available for testing integrated circuits or chips, the test system being configured to provide a test signal from a test driver via a primary test channel and to distribute the test signal via parallel wiring paths to a plurality of contact pads of one or more integrated circuits or chips under test, the test system having at least one operational amplifier arranged in the wiring path connected to the contact pads of the integrated circuits or chips.

According to another embodiment, a method is provided for testing integrated circuits or chips, in which a test signal is provided from a test driver via a primary test channel and distributed via parallel wiring paths to a plurality of contact pads of one or more integrated circuits or chips under test, wherein the test signal is provided to the contact pads of the integrated circuits or chips by at least one operational amplifier arranged in each wiring path.

By the arrangement of operational amplifiers into the wiring paths providing a test signal from the test driver to the contact pads of the integrated semiconductor circuits or chips, the system may provide the following features:

The integrated circuits or chips under test connected to the same tester channels, but not to the same operational amplifier, can be decoupled from each other, thereby a yield increase of the test system may be achieved.

The test signal may be individually amplified by the operational amplifier for each integrated circuit or chip.

High current can be delivered to the integrated circuits or chips without having voltage drop.

Depending on the wiring of the operational amplifier, the test signals or control signals to different contact pads of the tested integrated circuits or chips can be provided with different voltage levels.

The improvement of the shared driver concept involves a small effort, but a good impact for a better yield, better test coverage and higher parallelism of the test system.

In general, the present invention reduces the above mentioned problems of conventional technologies by decoupling shared good or well functioning chips from the negative interaction by shared defective chips. Thus, a yield increase may be achieved. By decoupling ungated internal voltages could be shared, which was not possible with the current sharing wiring of a conventional test system. Thus, an increase parallelism may be achieved. Increasing signal quality and the number of shared chips may increase fanout or branching. By increasing the current deliver capability without voltage loss an enhanced test coverage may be achieved. Several voltage levels may be provided by using active components, e.g., operational amplifiers connected to one shared tester channel only.

According to one embodiment, an operational amplifier is put into the wiring path which provides a test signal from the test driver to the contact pad of the integrated semiconductor circuits or chips.

According to one embodiment, the operational amplifiers may be installed into each parallel wiring path.

According to another embodiment, the operational amplifiers may be electrically installed into each wiring path after bifurcation of the shared driver channel or primary tester channel, before bifurcation, or before and after (having multiple bifurcation stages) bifurcation of the parallel wiring paths.

The wiring paths may be part of a test system. In one embodiment, the wiring paths may be part of an interface between the tested integrated circuits or chips and the test system, e.g., a probe card.

According to another embodiment, an operational amplifier may be electrically installed into the wiring the test system after bifurcation of the primary tester channel or shared driver channel. In other words, an operational amplifier may be arranged into each wiring path leading to a contact pad of a tested integrated circuit or chip, after bifurcation of the shared signal of the primary tester channel or shared driver channel. By this, unfavourable influence on the test results can be decreased, if one wire of the test system or probe card is connected after the operational amplifier to a short-circuit due to a defective integrated circuit or chip under testing.

Owing to the fact that the test system includes an operational amplifier arranged in each parallel wiring path that receives the test signal from the test driver amplifier DRV before feeding it to the input pads of the integrated semiconductor circuit(s) or chip(s), only the individual wiring path or sub-channel is affected by a potential short-circuit or defect in the related integrated circuit or chip under test, but not the whole shared driver test arrangement.

The operational amplifiers may be configured to provide test signals, control signals and/or current supply to the integrated circuits or chips. The operational amplifiers may be further configured to receive return signals from the integrated circuits or chips. Hence, the current may be provided to the integrated circuit or chip under test by the operational amplifier and no longer by the tester driver of the test system, leading to the benefit of less voltage drop when the integrated circuit or chip is consuming current on the respective contact pad (e.g., internal voltage pad) of the integrated circuit or chip.

The number of connected contact pads of the integrated circuit or chip under testing can be increased (higher sharing), wherein the connected pads are having a similar signal quality using operational amplifiers with low sharing fanout or branching.

According to another embodiment, an operational amplifier may be electrically installed into the parallel wiring paths of the test system before and after bifurcation of the primary test channel or shared driver channel. The wiring paths may be part of the test system or interface between the tested integrated circuits or chips and the test system, e.g., a probe card. Thus, an operational amplifier is put into the wiring path of the test system after bifurcation, but another wiring branching may be provided to contact several pads. This increases the number of contact pads delivered with acceptable signal quality, but keeping the number of used active elements low. Thus, the contact pads of the integrated circuits or chips under testing can be provided with more current than the tester driver could deliver without having a high voltage drop.

Furthermore, an increase of parallelism and an increased wiring fanout or wiring branching can be achieved. Depending on the wiring of the operational amplifier control signals, different pads of the integrated circuits or chips can be provided with different voltage levels.

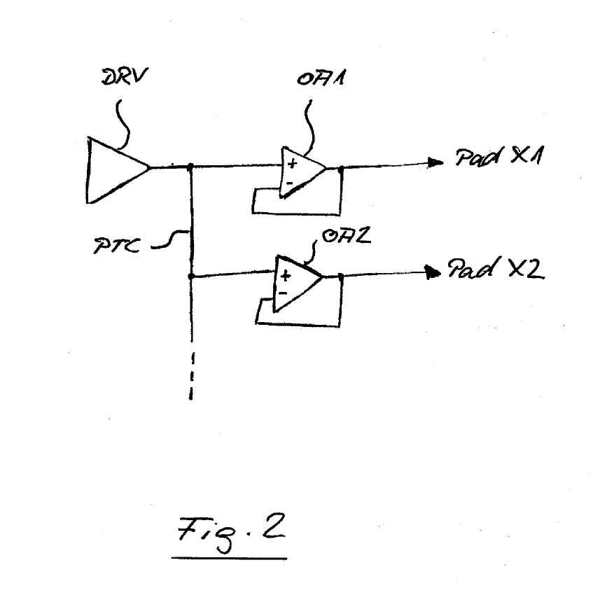

FIG. 2 illustrates one embodiment of a test system. The test system using the shared driver concept includes a test driver or shared driver DRV which generates and/or amplifies a test signal and provides it to a shared driver channel or primary tester channel PTC. The primary tester channel PTC is bifurcated, i.e. connected to a plurality of parallel sub-channels or wiring paths transmitting the test signal to connection pads X of integrated circuits or chips under test. In the embodiment illustrated in FIG. 2, two only two wiring paths are indicated connecting the primary tester channel PTC with pads X1 and X2 of integrated circuits or chips to be tested. However, an arbitrary plurality of sub-channels or wiring paths can be provided connecting the primary tester channel PTC with pads Xn of integrated circuits or chips to be tested.

After bifurcation of the primary test channel PTC an operational amplifier OA1 and OA2 is electrically installed into each parallel wiring path. The parallel wiring paths and/or the operational amplifiers OA1, OA2 may be part of a test system. Alternatively, the wiring paths and/or the operational amplifiers OA1, OA2 may be part of an interface between the tested integrated circuits or chips and the test system, e.g., a probe card.

The operational amplifiers OA1, OA2 include a negative and a positive input and one output connected to the input pad X of the tested integrated circuit or chip. The positive input of the operational amplifiers OA1, OA2 are connected to the primary test channel PTC, respectively. The negative input of the operational amplifiers OA1, OA2 is connected to the output of the operational amplifier and thus connected with the input pad X of the tested integrated circuit or chip. Thereby, any short-circuit or defect in the tested integrated circuit or chip causing a return signal with an input impedance of 0 Ohms can be blocked by the operational amplifier OA1, OA2 and does not imply any impact on other integrated circuits or chips connected to the same primary test channel PTC.

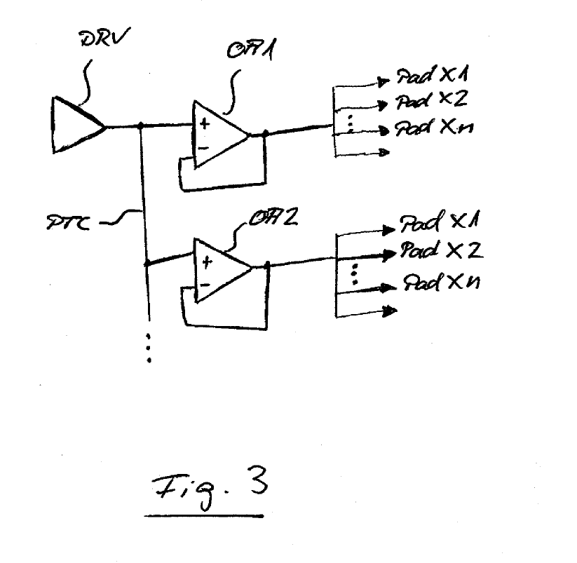

FIG. 3 illustrates another embodiment of a test system. In this embodiment, the operational amplifiers OA1, OA2 are arranged into each wiring path after bifurcation of the primary tester channel PTC, and before further bifurcation of the sub-channel or parallel wiring connected to the integrated circuits or chips under testing. Thus, one output of the operational amplifiers OA1, OA2 is connected to a plurality of contact pads X1, X2, . . . , Xn of the integrated circuits or chips. Hence, this embodiment of a test system illustrated in FIG. 3 includes multiple bifurcation stages, i.e. bifurcation of the shared driver channel or primary tester channel PTC and bifurcation of the sub-channel or parallel wiring connected to the integrated circuits or chips under testing. As an alternative, the operational amplifiers OA1, OA2 may be arranged after the bifurcation of the sub-channel or parallel wiring.

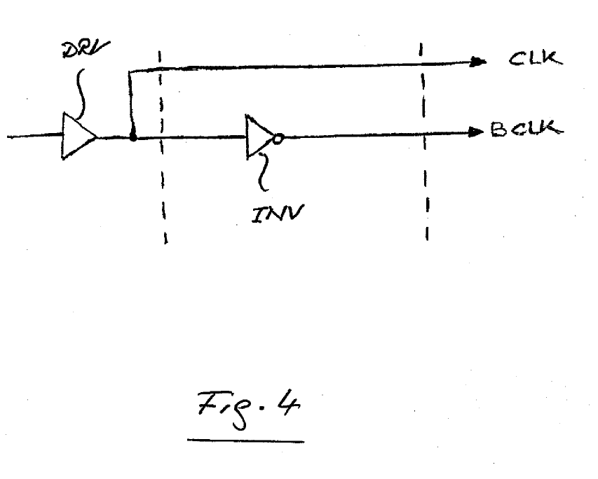

FIG. 4 illustrates another embodiment of a test system, wherein differential signals can be created by using an inverter INV arranged in the wiring path after the branching of the primary tester channel. By providing an inverter INV after the branching of the tester signal path, a differential signal BCLK can be created from the test signal CLK and both signals CLK and BCLK can be given to differential contact pads of the integrated circuit or chip under test in parallel. An additional signal delay caused by the inverter stage INV may be compensated in the respective wiring path or line by using appropriate active components, so that both signals CLK an BCLK arrive at the integrated circuit or chip at the same time. In addition, further branching of the respective lines is possible, in order to give both differential signals to several chips in parallel (not illustrated in the figure).

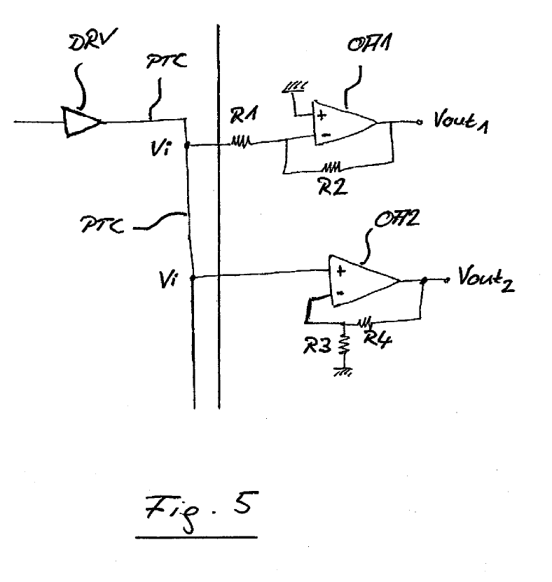

FIG. 5 illustrates another embodiment of a test system. In this embodiment, a resistance R1 may be provided in the line between the primary test channel PTC coming from the test driver DRV and the negative input of a first operational amplifier OA1, and another resistance R2 may be provided in the line in parallel to the first operational amplifier OA1 connecting the negative input and the output of the first operational amplifier OA1, whereas the positive input of the operational amplifier OA1 is connected to ground.

In one embodiment, a resistance R4 may be provided in the line between the negative input of a second operational amplifier OA2 and the output of the operational amplifier OA2 connected to the contact pad of an integrated circuit or chip under test, and another resistance R3 may be arranged between the negative input of the second operational amplifier OA2 and ground. The positive input of the second operational amplifier OA2 is connected to the primary test channel PTC coming from the test driver DRV.

In this embodiment, the output voltage provided from the first operational amplifier OA1 to the contact pad of the tested integrated circuit or chip is calculated as follows:

Vout₁=−Vi*(R2/R1)

The output voltage provided from the second operational amplifier OA2 to the contact pad of the tested integrated circuit or chip is calculated as follows:

Vout₂=−Vi*(R3+R4)/R3

whereas Vi is the internal voltage provided by the test driver DRV via the primary test channel PTC.

With this embodiment, even using only one primary tester channel PTC, different voltages can be created for different contact pads of the tested integrated circuits or chips. Choosing the value of the resistances R1, R2, R3 and R4, different voltages Vout₁ and Vout₂ can be generated from only one reference value Vi. In other words, one tester channel is used for various contact pads of one integrated circuit or chip to be tested. This sharing concept can increase the parallelism of the testing process using the shared driver concept.

While specific configurations and arrangements are discussed, it should be understood that this is done for illustrative purposes only. A person skilled in the pertinent art will recognize that other configurations and arrangements can be used without departing from the spirit and scope of the present invention. It will be apparent to a person skilled in the pertinent art that various embodiments can also be employed in a variety of other applications.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A system for testing integrated circuits or chips, comprising:
a test system being configured to provide a test signal from a test driver via a primary test channel and to distribute the test signal via parallel wiring paths to a plurality of contact pads of one or more integrated circuits or chips under test,
the test system having at least one operational amplifier arranged in the wiring path connected to the contact pads of the integrated circuits or chips.

2. The system of claim 1, comprising wherein at least one operational amplifier is arranged in each wiring path connected to the contact pads of the integrated circuits or chips to provide test signals, control signals and/or current supply to the integrated circuits or chips.

3. The system of claim 1, comprising wherein the operational amplifiers are electrically installed into the wiring paths after bifurcation of the primary test channel.

4. The system of claim 1, comprising wherein the operational amplifiers are electrically installed into the wiring paths before bifurcation of the wiring paths.

5. The system of claim 1, comprising wherein the operational amplifiers are configured to decouple the integrated circuits or chips from each other.

6. The system of claim 1, comprising wherein the operational amplifiers are configured to modify the test signal received from the primary test channel and to provide the modified test signal to the contact pads of the integrated circuits or chips under test.

7. The system of claim 1, comprising wherein the operational amplifiers are configured to provide test signals or control signals with different voltage levels to different contact pads of the tested integrated circuits or chips.

8. The system of claim 1, comprising wherein the operational amplifiers are configured to deliver test signals or control signals with different voltage levels to different contact pads of the tested integrated circuits or chips without causing voltage drop on the primary test channel.

9. The system of claim 1, comprising wherein the operational amplifiers are configured to block a return signal from a tested integrated circuit or chip, if the integrated circuit or chip causes a return signal with low impedance.

10. The system of claim 1, further comprising at least one an inverter arranged in the wiring path, the inverter being configured to provide differential signals to differential contact pads of the integrated circuit or chip under test in parallel.

11. The system of claim 10, comprising wherein the inverter is installed in the wiring path after branching of the primary tester channel.

12. The system of claim 11, comprising wherein a signal delay caused by the inverter is compensated in the respective wiring path, so that the differential signals arrive at the integrated circuit or chip substantially at the same time.

13. The system of claim 1, comprising wherein the wiring paths are part of the system or part of an interface between a test system for testing integrated circuits or chips with the integrated circuits or chips to be tested, in one embodiment, a probe card.

14. The system of claim 1, comprising:
a first resistance arranged in the line between the primary test channel coming from the test driver and a negative input of a first operational amplifier; and
a second resistance arranged in the line in parallel to the first operational amplifier, the second resistance connecting the negative input and the output of the first operational amplifier which is connected to an integrated circuit or chip under test, and the positive input of the first operational amplifier is connected to ground.

15. The system of claim 14, comprising:
the positive input of a second operational amplifier connected to the primary test channel coming from the test driver;
a third resistance arranged between the negative input of the second operational amplifier and ground; and
a fourth resistance arranged in the line between the negative input of the second operational amplifier, and the output of the second operational amplifier which is connected to an integrated circuit or chip under test.

16. The system of claim 15, comprising wherein the value of the first, second, third and/or fourth resistances are configured to generate different output voltages of the operational amplifiers from the reference voltage of the primary test channel, and the different voltages are provided from the outputs of the operational amplifiers to different contact pads of the integrated circuits or chips.

17. An interface or probe card for connecting a test system for testing integrated circuits or chips with said integrated circuits or chips to be tested comprising:
a primary test channel;
a plurality of parallel wiring paths, each wiring path configured to have a first end coupled to the primary test channel and a second end configured to be coupled to an input of separate integrated circuits or chips under test; and
a plurality of operational amplifiers arranged in each wiring path, wherein the operational amplifiers decouple the integrated circuits or chips from each other and provide separate test signals to the respective integrated circuit or chip.

18. A system for testing integrated circuits or chips comprising:
means for providing a primary test signal;
means for distributing the primary test signal to a plurality of integrated circuits or chips to be tested; and
active components to decouple the tested integrated circuits or chips from each other and to provide a separate test signal to each integrated circuit or chip.

19. The system of claim 18, wherein the active components comprise at least one operational amplifier connected to contact pads of the integrated circuits or chips.

20. A method for testing integrated circuits or chips, comprising:
providing a test signal from a test driver via a primary test channel; and
distributing the test signal via parallel wiring paths to a plurality of contact pads of one or more integrated circuits or chips under test, including providing the test signal to the contact pads of the integrated circuits or chips by at least one operational amplifier arranged in each wiring path.

21. The method of claim 20, further comprising:
decoupling the tested integrated circuits or chips from each other by the operational amplifiers.

22. The method of claim 20, further comprising:
individually modifying test signals, control signals and/or current supply to the integrated circuits or chips by the operational amplifiers for each integrated circuit or chip.

23. The method of claim 20, further comprising:
individually amplifying the test signal by the operational amplifier for each integrated circuit or chip.

24. The method of claim 20, further comprising:
providing provide test signals, control signals and/or current supply to the integrated circuits or chips with different voltage levels to different contact pads of the tested integrated circuits or chips.

25. The method of claim 20, further comprising:
delivering high current to the tested integrated circuits or chips without causing voltage drop on the primary test channel.
